(19) United States
(12) Patent Application Publication
(10) Pub. No.: US 2026/0130170 A1
(43) Pub. Date: May 7, 2026

(54) SUBSTRATE PROCESSING APPARATUS

(71) Applicant: SAMSUNG ELECTRONICS CO.,LTD., Suwon-si (KR)

(72) Inventors: Dain SONG, Suwon-si (KR); Hachul SHIN, Suwon-si (KR); Dongwook KIM, Suwon-si (KR); Donghyeong KIM, Suwon-si (KR); IIhwan KIM, Suwon-si (KR); Jeonghun KIM, Suwon-si (KR); Eunhee JEANG, Suwon-si (KR)

(73) Assignee: SAMSUNG ELECTRONICS CO.,LTD., Suwon-si (KR)

(21) Appl. No.: 19/226,697

(22) Filed: Jun. 3, 2025

(30) Foreign Application Priority Data
Nov. 1, 2024 (KR) 10-2024-0153788

(51) Int. Cl. H01L 21/68; G03F 7/00; G03F 9/00

(52) U.S. Cl. CPC H10P 72/53; G03F 7/70033; G03F 7/702; G03F 7/70233; G03F 9/7065; G03F 9/7076; G03F 9/7084; G03F 9/7088

(57) ABSTRACT

A substrate processing apparatus includes: a semiconductor substrate including a base layer, a first layer on the base layer, a second layer on the first layer, and alignment marks in the first layer and the second layer; and a measuring apparatus configured to analyze the plurality of alignment marks of the semiconductor substrate. The alignment marks include first alignment keys in the first layer and second alignment keys in the second layer. In a plan view, the first alignment keys extend along a first horizontal direction, and the second alignment keys extend along a third horizontal direction,. The first alignment keys and the second alignment keys overlap along a vertical direction.

### CROSS-REFERENCE TO RELATED APPLICATION

This application is based on and claims priority to Korean Patent Application No. 10-2024-0153788, filed on Nov. 1, 2024, in the Korean Intellectual Property Office, the disclosure of which is incorporated by reference herein in its entirety.

### BACKGROUND

The present disclosure relates to a substrate processing apparatus, and more particularly, to a substrate processing apparatus which processes a substrate including an alignment mark.

In response to the rapid development of the electronics industry and the needs of users, electronic devices are further miniaturized and multi-functionalized, and have a large capacity, and accordingly, highly integrated semiconductor chips are required. Accordingly, research is continuing in an effort to reduce overlay errors of semiconductor chips in line with the demand for high integration.

### SUMMARY

One or more example embodiments provide a substrate processing apparatus having a small overlay error due to an increase in the measurement speed and the number of measurement samples of the alignment mark.

However, issues to be solved by example embodiments are not limited to the above-mentioned issues, and other issues not mentioned may be clearly understood by those of ordinary skill in the art from the following descriptions.

According to an aspect of an example embodiment a substrate processing apparatus includes: a semiconductor substrate including a base layer, a first layer on the base layer, a second layer on the first layer, and a plurality of alignment marks in the first layer and the second layer; and a measuring apparatus configured to analyze the plurality of alignment marks of the semiconductor substrate. The plurality of alignment marks include a plurality of first alignment keys in the first layer and a plurality of second alignment keys in the second layer. In a plan view, the plurality of first alignment keys extend along a first horizontal direction, and are apart from each other along a second horizontal direction perpendicular to the first horizontal direction. In the plan view, the plurality of second alignment keys extend along a third horizontal direction, and are apart from each other along a fourth horizontal direction perpendicular to the third horizontal direction. The plurality of first alignment keys and the plurality of second alignment keys overlap along a vertical direction.

According to another aspect of an example embodiment a substrate processing apparatus includes: a semiconductor substrate including a base layer, a first layer on the base layer, a second layer on the first layer, and a plurality of alignment marks in the first layer and the second layer; and a measuring apparatus configured to analyze the plurality of alignment marks of the semiconductor substrate. The plurality of alignment marks include a plurality of first alignment keys in the first layer and a plurality of second alignment keys. Each of the plurality of second alignment keys has a protrusion shape extending in a vertical direction. In a plan view, the plurality of second alignment keys are arranged in a matrix shape in which a plurality of columns apart from each other along a first horizontal direction and a plurality of rows apart from each other along a second horizontal direction perpendicular to the first horizontal direction are arranged.

According to another aspect of an example embodiment a substrate processing apparatus includes: an extreme ultra-violet (EUV) light source; a mask stage; a first optical device configured to allow EUV light from the EUV light source to be incident on an EUV mask on the mask stage; a semiconductor substrate including a base layer, a first layer on the base layer, a second layer on the first layer, and a plurality of alignment marks in the first layer and the second layer; a wafer stage configured to support the semiconductor substrate; a second optical device configured to allow the EUV light reflected by the EUV mask to be incident on the semiconductor substrate; and a measuring apparatus configured to analyze the plurality of alignment marks of the semiconductor substrate. Each of the plurality of alignment marks includes a plurality of first alignment keys in the first layer and a plurality of second alignment keys. The plurality of first alignment keys and the plurality of second alignment keys overlap along a vertical direction.

### BRIEF DESCRIPTION OF DRAWINGS

The above and other objects, features and advantages will be more apparent from the following description of example embodiments, taken in conjunction with the accompanying drawings, in which:

FIG. 1 is a schematic conceptual diagram of a substrate processing apparatus according to some example embodiments;

FIG. 2 is a detailed block diagram of a control device in the substrate processing apparatus of FIG. 1 according to some example embodiments;

FIG. 3 is a schematic plan view of a semiconductor substrate according to some example embodiments;

FIG. 4 is a schematic plan view of alignment marks of the semiconductor substrate of FIG. 3 according to some example embodiments;

FIGS. 5A and 5B are schematic cross-sectional views of alignment marks in FIG. 4 taken along lines X1-X1′ and Y1-Y1′ in FIG. 4, respectively according to some example embodiments;

FIG. 6 is a schematic enlarged view of portion “EX” in the alignment mark of FIG. 4 according to some example embodiments;

FIG. 7 illustrates schematic diagrams of a process of processing data measured by a measuring apparatus, according to some example embodiments;

FIGS. 8A and 8B are schematic cross-sectional views of cut portions of an alignment mark, according to some example embodiments;

FIG. 9 is a schematic plan view of an alignment mark according to some example embodiments;

FIG. 10 is a schematic plan view of an alignment mark according to some example embodiments;

FIG. 11 is a schematic plan view of an alignment mark of a semiconductor substrate, according to some example embodiments;

FIGS. 12A and 12B are schematic cross-sectional views of an alignment mark in FIG. 11 taken along lines X2-X2′ and Y2-Y2′ in FIG. 11, respectively according to some example embodiments;

FIGS. 13A and 13B are schematic cross-sectional views of cut portions of an alignment mark, according to some example embodiments;

FIG. 14 is a schematic plan view of an alignment mark according to some example embodiments;

FIG. 15 is a schematic cross-sectional view of the alignment mark in FIG. 14 taken along line X4-X4′ in FIG. 14 according to some example embodiments; and

FIG. 16 is a schematic cross-sectional view of a cut portion of an alignment mark, according to some example embodiments.

### DETAILED DESCRIPTION

Hereinafter, example embodiments will be described with reference to the accompanying drawings. Embodiments described herein are example embodiments, and thus, the present disclosure is not limited thereto, and may be realized in various other forms. Each example embodiment provided in the following description is not excluded from being associated with one or more features of another example or another example embodiment also provided herein or not provided herein but consistent with the present disclosure.

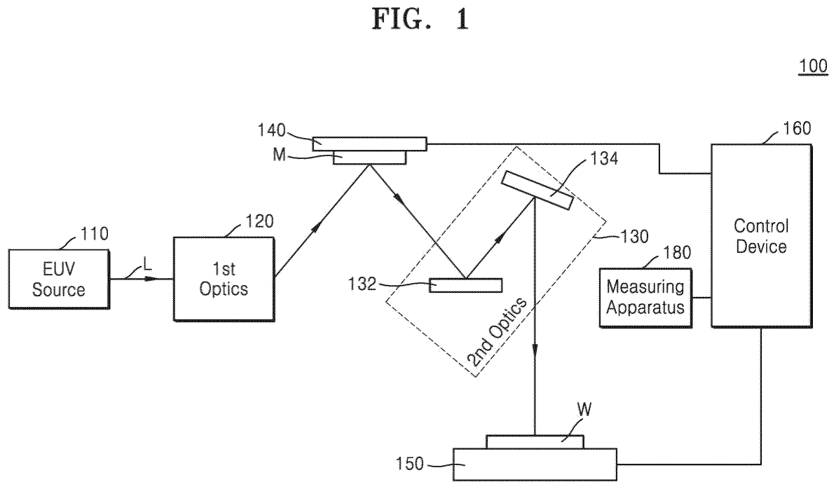

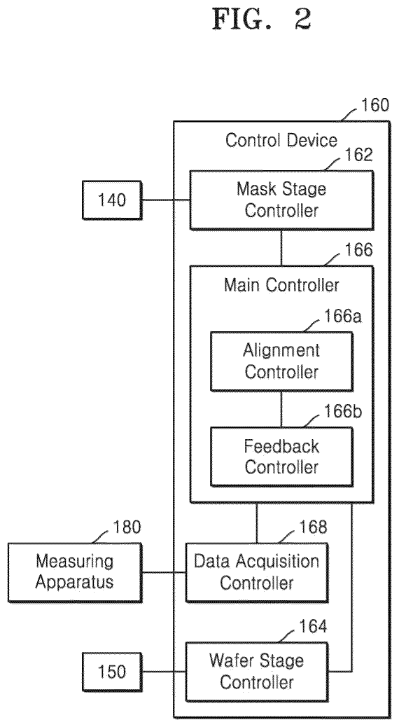

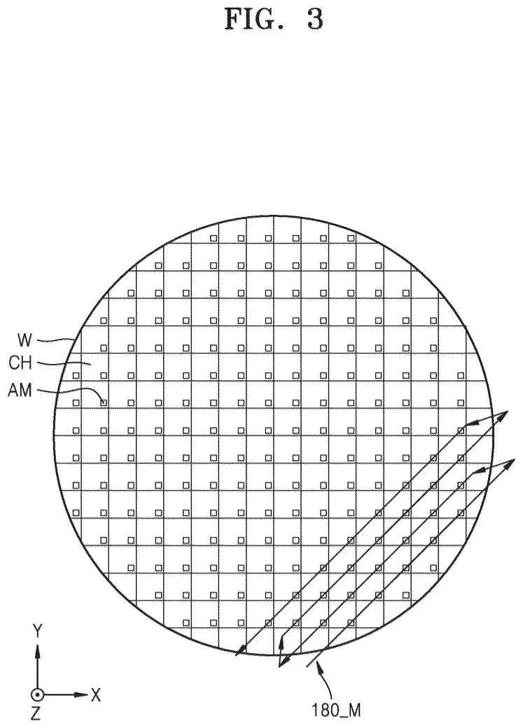

FIG. 1 is a schematic conceptual diagram of a substrate processing apparatus 100 according to some example embodiments. FIG. 2 is a detailed block diagram of a control device 160 in the substrate processing apparatus 100 of FIG. 1. FIG. 3 is a schematic plan view of a semiconductor substrate W according to some example embodiments.

Referring to FIGS. 1 and 2, the substrate processing apparatus 100 may be an extreme ultra-violet (EUV) exposure apparatus. The substrate processing apparatus 100 may include an EUV source 110, a first optics (i.e., first optical device) 120, a second optics (i.e., second optical device) 130, a mask stage 140, a wafer stage 150, the control device 160, and a measuring apparatus 180.

Hereinafter, unless specifically defined, a direction in parallel with an upper surface of the semiconductor substrate W may be defined as the X direction, a direction perpendicular to the upper surface of the semiconductor substrate W may be defined as the Z direction (or vertical direction), and a direction perpendicular to the X direction and the Z direction may be defined as the Y direction (refer to FIG. 3). A horizontal direction may be defined as a direction in which the X direction and the Y direction are combined.

The EUV source 110 may generate and output EUV light L of a high energy density within a wavelength range of about 5 nm to about 50 nm. For example, the EUV source 110 may generate and output the EUV light L having a high energy density of about 13.5 nm wavelength. The EUV source 110 may include a plasma-based light source or a synchrotron radiation light source. In this case, the plasma-based light source may indicate a light source that generates plasma and uses light emitted by the plasma, and may include a laser-produced plasma (LPP) light source, a discharge-produced plasma (DPP) light source, etc.

The first optics 120 may include a plurality of mirrors. For example, in the substrate processing apparatus 100, the first optics 120 may include two or three mirrors. For example, the EUV light L from the EUV source 110 may be incident on an EUV mask M arranged on the mask stage 140 by reflection by the mirrors in the first optics 120.

The EUV mask M may include a reflection-type mask including a reflective region and a non-reflective and/or intermediate reflective region. The EUV mask M may include a reflective multilayer layer for reflecting the EUV light L and an absorption layer pattern formed on the reflective multilayer layer on a substrate including a low thermal expansion coefficient material (LTEM) such as quartz, and an absorption layer pattern formed on the reflective multilayer.

The EUV mask M reflects the EUV light L incident through the first optics 120 and guide the reflected EUV light L to be incident on the second optics 130. In some example embodiments, the EUV mask M may structuralize the EUV light L from the first optics 120 according to a pattern shape including a reflective multilayer and an absorbing layer on the EUV mask M, and guide the structuralized EUV light L to be incident on the second optics 130. The structuralized EUV light L may be incident on the second optics 130 while indicating information in the form of a pattern on the EUV mask M, and may be transmitted by the second optics 130 and be projected on the semiconductor substrate W, which is an EUV exposure target, so that an image corresponding to the pattern shape is formed. In this case, the semiconductor substrate W may include a substrate including a semiconductor material such as silicon, for example, a wafer.

The second optics 130 may include a plurality of mirrors. As shown in FIG. 1, the second optics 130 may include two mirrors, that is, a first mirror 132 and a second mirror 134. However, example embodiments are not limited thereto and the second optics 130 may include more than two mirrors. For example, in the substrate processing apparatus 100, the second optics 130 may include four to eight mirrors.

As described above, the second optics 130 may transmit the EUV light L reflected by the EUV mask M to the semiconductor substrate W by using the reflection of the mirrors. In addition, the second optics 130 may allow (i.e., direct) the EUV light L to be incident on an upper surface of the semiconductor substrate W at a certain inclination.

The EUV mask M may be arranged on the mask stage 140. The mask stage 140 may move in the X direction, the Y direction, and the Z direction in the process of arranging the EUV mask M.

The semiconductor substrate W may be arranged on the wafer stage 150. The wafer stage 150 may move in the X direction, the Y direction, and the Z direction, and may move in the Z direction perpendicular to an X-Y plane. In addition, the wafer stage 150 may rotate on the X-Y plane with respect to a Z-axis extending in the Z direction, as a reference, or may rotate on a Y-Z plane or an X-Z plane with respect to any axis on the X-Y plane, for example, the X-axis extending in the X direction or the Y-axis extending in the Y direction, as a reference.

As the wafer stage 150 moves and rotates, the semiconductor substrate W arranged on the wafer stage 150 may move in the X direction, the Y direction, or the Z direction, and in addition, may rotate with respect to the X direction, the Y direction, or the Z direction, as a reference.

The control device 160 may control the mask stage 140 and the wafer stage 150. The control device 160 may include a mask stage controller 162, a wafer stage controller 164, a main controller 166, and a data acquisition controller 168.

The mask stage controller 162 may control the movement of the mask stage 140. The wafer stage controller 164 may control the movement of the wafer stage 150. The main controller 166 may control entirely the mask stage controller 162 and the wafer stage controller 164. The data acquisition controller 168 may obtain data for a plurality of alignment marks AM from the measuring apparatus 180, and transmit the data to the main controller 166.

The main controller 166 may include an alignment controller 166a and a feedback controller 166b. In some example embodiments, the main controller 166 may further include various components for the control in the EUV exposure process. For example, the main controller 166 may include a focus controller, a data storage device, an exposure processor, etc.

The alignment controller 166a may calculate an overlay error correction value. The alignment controller 166a may calculate the overlay error correction value based on a correlation between data for a plurality of alignment marks AM measured by using the measuring apparatus 180, and the plurality of alignment marks AM.

An overlay error may indicate an overlay difference between a past layer corresponding to an under layer and a current layer corresponding to an upper layer. In general, the overlay error may be reduced by taking a shot according to the under layer based on the plurality of alignment marks AM of the under layer during the exposure process of the upper layer.

The feedback controller 166b may feedback the calculated overlay error correction value to the mask stage controller 162 and/or the wafer stage controller 164. The mask stage controller 162 and/or the wafer stage controller 164 may control the movement of the mask stage 140 and/or the wafer stage 150 based on the overlay error correction value.

The measuring apparatus 180 may measure the overlay error of patterns on the semiconductor substrate W. For example, the measuring apparatus 180 may measure the overlay error by measuring the plurality of alignment marks AM of the semiconductor substrate W.

In some example embodiments, the measuring apparatus 180 may include an optical microscope, or an electron microscope, such as scanning electron microscope (SEM) and a transmission electron microscope (TEM). For example, the measuring apparatus 180 may use, as a measuring method, ellipsometry, such as imaging ellipsometry (IE) and spectroscopic imaging ellipsometry (SIE).

The substrate processing apparatus 100 may include the measuring apparatus 180. However, example embodiments are not limited thereto, and the measuring apparatus 180 may also be separate from the substrate processing apparatus 100. On the other hand, the measurement of the overlay error of the semiconductor substrate W by using the measuring apparatus 180 may be performed by using an after development inspection (ADI) and an after cleaning inspection (ACI).

For example, when the measuring apparatus 180 is included in the substrate processing apparatus 100, the main controller 166 may further include a measurement controller. The measurement controller may control the measuring apparatus 180 so that the measuring apparatus 180 measures the plurality of alignment marks AM.

In some example embodiments, the measuring apparatus 180 may measure the plurality of alignment marks AM as the measuring apparatus 180 moves on the upper portion of the plurality of alignment marks AM of the semiconductor substrate W. For example, a movement path 180_M of the measuring apparatus 180 may extend over the plurality of alignment marks AM of the semiconductor substrate W, and may pass over each of the plurality of alignment marks AM a single time. The measuring apparatus may measure the plurality of alignment marks AM while moving along the movement path 180_M on the upper portion of the semiconductor substrate W. The movement path 180_M may extend along a direction inclined in the Y direction with respect to the X direction as a reference. The measuring apparatus 180 may scan each of the plurality of alignment marks AM once, and measure data of the plurality of alignment marks AM.

For example, referring to the movement path 180_M of the measuring apparatus 180 illustrated in FIG. 3, the measuring apparatus 180 may measure data of one alignment mark AM by passing the upper portion of one alignment mark AM only once. Accordingly, as the movement path 180_M of the measuring apparatus 180 is simplified, the time required for the measuring apparatus 180 to measure the plurality of alignment marks AM on the semiconductor substrate W may be reduced.

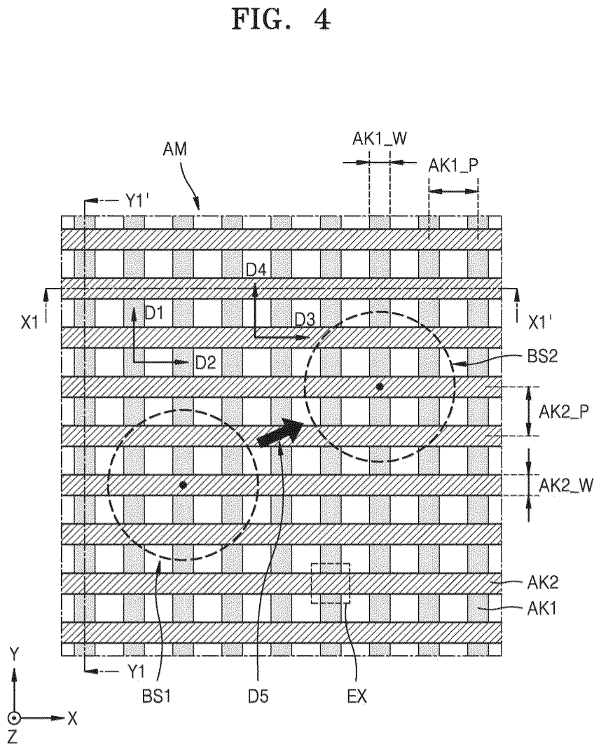

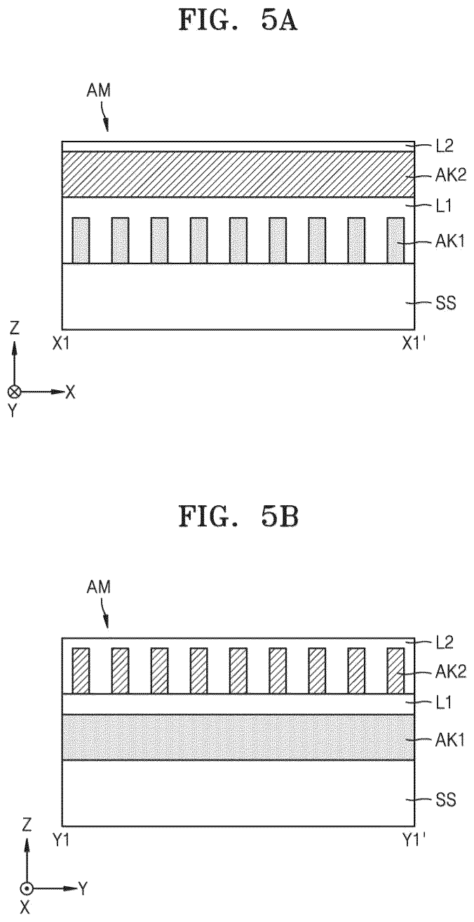

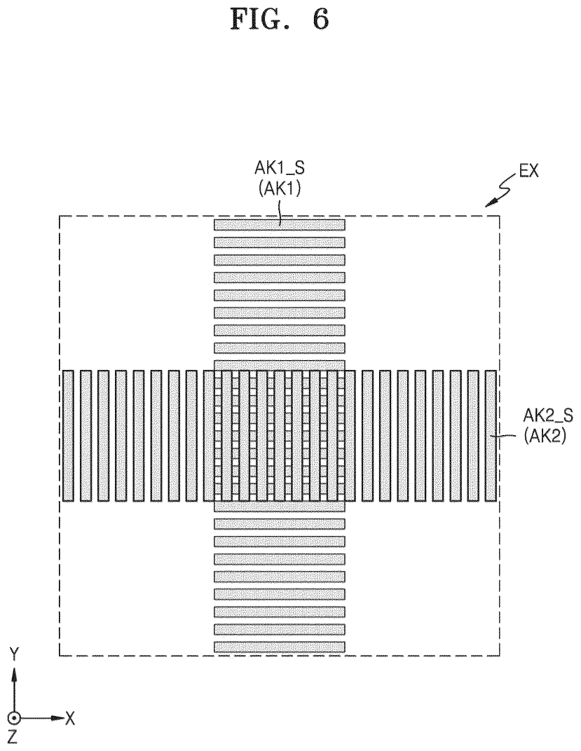

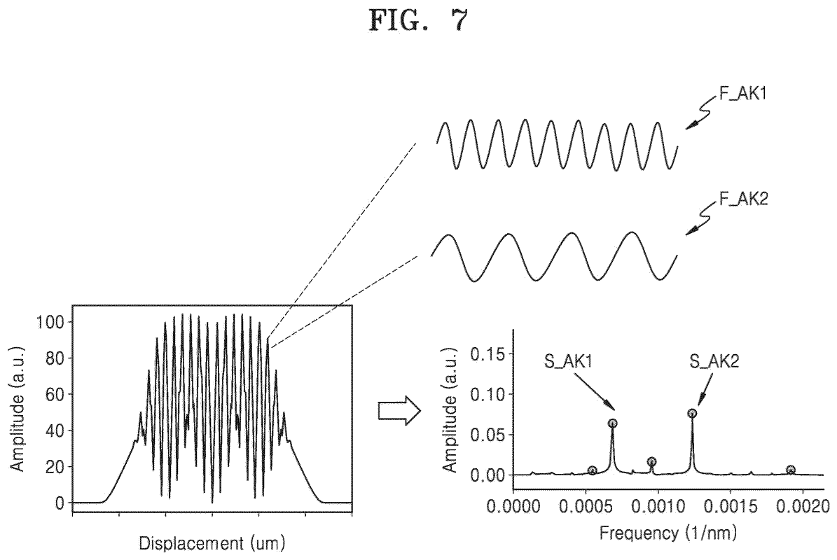

FIG. 4 is a schematic plan view of alignment marks AM of the semiconductor substrate W of FIG. 3. FIGS. 5A and 5B are schematic cross-sectional views of the alignment marks AM in FIG. 4 taken along lines X1-X1′ and Y1-Y1′ in FIG. 4, respectively. FIG. 6 is a schematic enlarged view of portion “EX” in the alignment mark AM of FIG. 4. FIG. 7 illustrates schematic diagrams of a process of processing data of the alignment mark AM measured by the measuring apparatus 180.

Referring to FIGS. 4 through 7 together with FIGS. 1 and 3, the semiconductor substrate W may include a base layer SS, a first layer L1, a second layer L2, and the plurality of alignment marks AM. A process of obtaining data of the plurality of alignment marks AM of the semiconductor substrate W by using the measuring apparatus 180 is described in detail with reference to FIGS. 4 through 7.

The semiconductor substrate W may have a wafer shape before a plurality of semiconductor chips CH are diced. Each of the plurality of semiconductor chips CH may include at least one alignment mark AM. For example, in the process of respectively forming a plurality of semiconductor devices on the plurality of semiconductor chips CH of the semiconductor substrate W, a plurality of first alignment keys AK1 and a plurality of second alignment keys AK2 of the alignment mark AM may be formed. The overlay error may be corrected based on values measured for the plurality of first alignment keys AK1 and the plurality of second alignment keys AK2.

The base layer SS may include, for example, a semiconductor material such as silicon (Si). Alternatively, the base layer SS may include a semiconductor material such as germanium (Ge).

The plurality of semiconductor devices may be on the base layer SS. The semiconductor devices on the base layer SS may include various microelectronic devices, for example, a metal-oxide-semiconductor field effect transistor (MOSFET) such as a complementary metal-oxide semiconductor (CMOS) transistor, system large scale integration (LSI), an image sensor such as CMOS imaging sensor (CIS), a micro-electro-mechanical system (MEMS), an active device, a passive device, etc.

Referring to FIGS. 5A and 5B, the first layer L1 may be on the base layer SS. The second layer L2 may be above the first layer L1. Each of the first layer L1 and the second layer L2 may include a semiconductor device, the alignment mark AM, and an insulating layer surrounding the semiconductor device and the alignment mark AM.

The first layer L1 may include the under layer, and the second layer L2 may include the upper layer. For example, after the first layer L1 is formed on the upper surface of the base layer SS, the second layer L2 may be sequentially formed on the first layer L1. However, the number of layers of the semiconductor substrate W is not limited thereto, and the semiconductor substrate W may include three or more layers.

The alignment mark AM may be inside the first layer L1 and the second layer L2. The alignment mark AM may include the plurality of first alignment keys AK1 on the first layer L1 and the plurality of second alignment keys AK2 on the second layer L2. In some example embodiments, the alignment mark AM may have a length of about 30 μm to about 60 μmin the X direction, and a length of about 30 μm to about 60 μm in the Y direction.

In some example embodiments, a vertical level of the plurality of first alignment keys AK1 may be lower than a vertical level of the plurality of second alignment keys AK2. For example, the plurality of first alignment keys AK1 may be below the plurality of second alignment keys AK2 in a vertical direction (Z direction).

Referring to FIG. 4, in a plan view, the plurality of first alignment keys AK1 may extend in a first horizontal direction D1 and may be apart from each other in a second horizontal direction D2 perpendicular to the first horizontal direction D1. In a plan view, the plurality of second alignment keys AK2 may extend in a third horizontal direction D3, and may be apart from each other in a fourth horizontal direction D4 perpendicular to the third horizontal direction D3. As used herein, the plan view may indicate a view looking at the X-Y plane.

In some example embodiments, the third horizontal direction D3 may be the same direction as the second horizontal direction D2. For example, the plurality of second alignment keys AK2 may extend in the second horizontal direction D2, and may be apart from each other in the first horizontal direction D1. For example, the first horizontal direction D1 and the fourth horizontal direction D4 may be the Y direction, and the second horizontal direction D2 and the third horizontal direction D3 may be the X direction.

When a width of each of the plurality of first alignment keys AK1, for example, a length in the second horizontal direction D2 is a first width AK1_W, and a length of each of the plurality of second alignment keys AK2, for example, a length in the fourth horizontal direction D4 is a second width AK2_W, the first width AK1_W may be the same as the second width AK2_W.

When a distance between a center of each of the plurality of first alignment keys AK1 and an adjacent first alignment key AK1 (i.e., a pitch of the plurality of first alignment keys AK1) is a first distance AK1_P, and a distance between a center of each of the plurality of second alignment keys AK2 and an adjacent second alignment key AK2 (i.e., a pitch of the plurality of second alignment keys AK2) is a second distance AK2_P, the first distance AK1_P may be the same as the second distance AK2_P.

For example, in a plan view, the plurality of first alignment keys AK1 and the plurality of second alignment keys AK2 may be arranged to form a grid pattern. In some example embodiments, a portion of each of the plurality of first alignment keys AK1 may overlap a portion of each of the plurality of second alignment keys AK2 in the vertical direction (Z direction).

Portions where the plurality of first alignment keys AK1 overlap the plurality of second alignment keys AK2 in the vertical direction (Z direction) may be intersections of the grid pattern. For example, the plurality of second alignment keys AK2 may be above one first alignment key AK1, and the plurality of first alignment keys AK1 may be below one second alignment key AK2.

In some example embodiments, the plurality of first alignment keys AK1 may be apart from the plurality of second alignment keys AK2 in the vertical direction (Z direction). For example, an insulating layer of the first layer L1 may be between the plurality of first alignment keys AK1 and the plurality of second alignment keys AK2. However, example embodiments are not limited thereto, and upper surfaces of the plurality of first alignment keys AK1 may be in contact and coplanar with lower surfaces of the plurality of second alignment keys AK2.

Referring to FIG. 6, the plurality of first alignment keys AK1 may respectively include a plurality of first sub-segments AK1_S. For example, when one first alignment key AK1 is enlarged, the enlarged first alignment key AK1 may show a shape in which the plurality of first sub-segments AK1_S are apart from each other and arranged in a line.

The first alignment key AK1 may include the plurality of first sub-segments AK1_S, which extend in a direction perpendicular to the extending direction of the first alignment key AK1, and are arranged in the extending direction of the first alignment key AK1. For example, the plurality of first sub-segments AK1_S may extend in the second horizontal direction D2, and may be apart from each other in the first horizontal direction D1. For example, a length of the plurality of first sub-segments AK1_S in the second horizontal direction D2 may be the first width AK1_W of the first alignment key AK1.

The second alignment key AK2 may include a plurality of second sub-segments AK2_S, which extend in a direction perpendicular to the extending direction of the second alignment key AK2, are arranged in the extending direction of the second alignment key AK2. For example, the plurality of second sub-segments AK2_S may extend in the third horizontal direction D3, and may be apart from each other in the fourth horizontal direction D4. For example, a length of the plurality of second sub-segments AK2_S in the third horizontal direction D3 may be the second width AK2_W of the second alignment key AK2.

In the process of forming the plurality of first sub-segments AK1_S and the plurality of second sub-segments AK2_S, deformation may occur under each of the plurality of first sub-segments AK1_S and each of the plurality of second sub-segments AK2_S.

In some example embodiments, the first width AK1_W of the first alignment key AK1 may be less than the extension length of the first alignment key AK1. In this regard, a length of the first alignment key AK1 in the second horizontal direction D2 may be less than a length thereof in the first horizontal direction D1. Accordingly, the deformation of each of the plurality of first sub-segments AK1_S may be relatively small, when the plurality of first sub-segments AK1_S extend in the second horizontal direction D2 and are apart from each other in the first horizontal direction D1, rather than when the plurality of first sub-segments AK1_S extend in the first horizontal direction D1 and are apart from each other in the second horizontal direction D2.

In some example embodiments, the second width AK2_W of the second alignment key AK2 may be less than the extension length of the second alignment key AK2. In this regard, a length of the second alignment key AK2 in the fourth horizontal direction D4 may be less than the length thereof in the third horizontal direction D3. Accordingly, the deformation of each of the plurality of second sub-segments AK2_S may be relatively small, when the plurality of second sub-segments AK2_S extend in the fourth horizontal direction D4 and are apart from each other in the third horizontal direction D3, rather than when the plurality of second sub-segments AK2_S extend in the third horizontal direction D3 and are apart from each other in the fourth horizontal direction D4.

Because the degree of deformation of each of the plurality of first sub-segments AK1_S and each of the plurality of second sub-segments AK2_S is relatively small, a measurement error may be reduced, in the process of measuring the position of the alignment mark AM by using the measuring apparatus 180. In addition, because the degree of deformation of each of the plurality of first sub-segments AK1_S and each of the plurality of second sub-segments AK2_S is relatively small, in the process of processing the semiconductor substrate W, durability of the first alignment key AK1 and the second alignment key AK2 may be improved.

Referring to FIGS. 3, 4, and 7, a process of measuring the positions of the plurality of first alignment keys AK1 and the plurality of second alignment keys AK2 by using the measuring apparatus 180 is described.

The measuring apparatus 180 may move on an upper portion of each of the plurality of alignment marks AM in a fifth horizontal direction D5, and may measure the plurality of first alignment keys AK1 and the plurality of second alignment keys AK2 of each of the plurality of alignment marks AM.

For example, the measuring apparatus 180 may simultaneously measure the plurality of first alignment keys AK1 and the plurality of second alignment keys AK2 of the alignment mark AM, while passing on the upper portion of one alignment mark AM one time.

Because the measuring apparatus 180 may simultaneously measure the plurality of first alignment keys AK1 and the plurality of second alignment keys AK2 of the alignment mark AM, the measurement time may be reduced.

In some example embodiments, the fifth horizontal direction D5 may be a direction inclined toward the first horizontal direction D1 with respect to the second horizontal direction D2. For example, the fifth horizontal direction D5 may be inclined by about 20° to about 35° or about 55° to about 70° in the first horizontal direction D1 with respect to the second horizontal direction D2.

For example, when the first width AK1_W of the plurality of first alignment keys AK1 is the same as the second width AK2_W of the plurality of second alignment keys AK2, and when the first distance AK1_P, which is a separation distance between a center of each of the plurality of first alignment keys AK1 (i.e., a pitch of the plurality of first alignment keys AK1), is the same as the second distance AK2_P, which is a separation distance between a center of each of the plurality of second alignment keys AK2, the fifth horizontal direction D5 may be offset from 0°, 45°, and 90° with respect to the second horizontal direction D2.

For example, while the measuring apparatus 180 moves a certain distance on the alignment mark AM, and the fifth horizontal direction D5 is not the same direction as at least one of the first horizontal direction D1 and the second horizontal direction D2, the number of first alignment keys AK1 and the number of second alignment keys AK2, which are passed by the measuring apparatus 180, may be different from each other.

Referring to FIG. 4, for example, when the measurement point measured by the measuring apparatus 180 moves along the fifth horizontal direction D5 from a first measurement point BS1 to a second measurement point BS2, the number of first alignment keys AK1 measured by the measuring apparatus 180 may be five and the number of second alignment keys AK2 measured by the measuring apparatus 180 may be three.

Accordingly, in the process of measuring the alignment mark AM by the measuring apparatus 180, during the same measurement time, the number of first alignment keys AK1 may be greater than the number of second alignment keys AK2, and thus a first measurement period F_AK1 of the first alignment key AK1 may be less than a second measurement period F_AK2 of the second alignment key AK2.

Referring to FIG. 7, a signal value, which is obtained by simultaneously measuring the plurality of first alignment keys AK1 and the plurality of second alignment keys AK2 while the measuring apparatus 180 passes above the upper portion of the alignment mark AM in the fifth horizontal direction D5, may be divided into a first signal S_AK1 of the first alignment key AK1 and a second signal S_AK2 of the second alignment key AK2, based on the first measurement period F_AK1 of the first alignment key AK1 and the second measurement period F_AK2 of the second alignment key AK2.

For example, the signal value according to the measurement position obtained by using the measuring apparatus 180 may be Fourier transformed into a signal value according to the measurement period, and divided into the first signal S_AK1 of the first alignment key AK1 and the second signal S_AK2 of the second alignment key AK2. The overlay error may be calculated based on the first signal S_AK1 of the first alignment key AK1 and the second signal S_AK2 of the second alignment key AK2, which are separated from each other.

Because the measuring apparatus 180 may simultaneously measure the plurality of first alignment keys AK1 and the plurality of second alignment keys AK2, an effective measurement length of the measuring apparatus 180 may increase. For example, the effective measurement length of the measuring apparatus 180 may be about 40 μm to about 70 μm. As the effective measurement length of the measuring apparatus 180 increases, the number of samples that the measuring apparatus 180 may obtain from one alignment mark AM increases, and thus the accuracy of correction of the overlay error may increase. In addition, because the effective measurement length of the measuring apparatus 180 is increased, the alignment mark AM may be miniaturized.

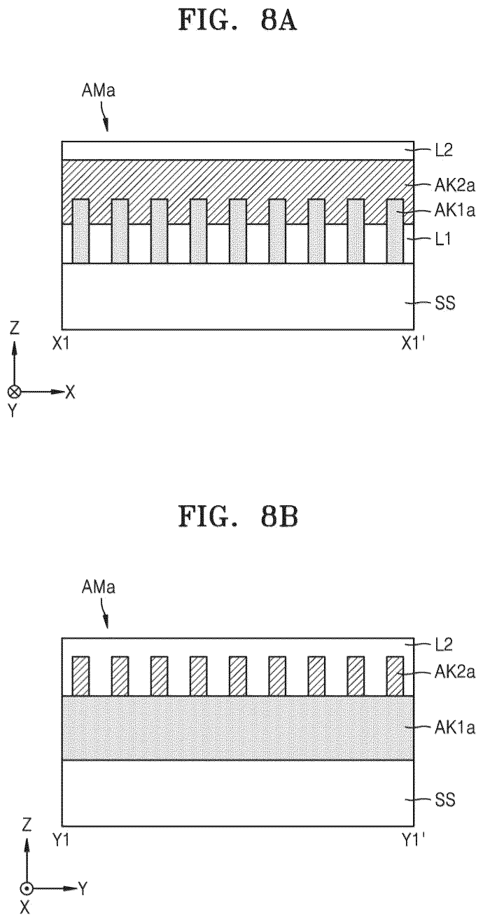

FIGS. 8A and 8B are schematic cross-sectional views of cut portions of an alignment mark AMa, according to example embodiments. For example, FIG. 8A is a cross-sectional view in which the alignment mark AMa is cut by a plane in parallel with the X-Z plane, and FIG. 8B is a cross-sectional view in which the alignment mark AMa is cut by a plane in parallel with the Y-Z plane, respectively.

Most of the components constituting the alignment mark AMa and the materials constituting the components may be substantially the same as or similar to those described with reference to FIGS. 5A and 5B. Accordingly, for convenience of description, the difference between the alignment mark AMa of FIGS. 8A and 8B and the alignment mark AM of FIGS. 5A and 5B described above is mainly described.

The alignment mark AMa may include a plurality of first alignment keys AK1a in the first layer L1 arranged on the base layer SS and a plurality of second alignment keys AK2a in the second layer L2 arranged on the first layer L1.

For example, as illustrated in FIG. 4, in a plan view, the plurality of first alignment keys AK1a and the plurality of second alignment keys AK2a of the alignment mark AMa may be arranged in a grid pattern.

Each of the plurality of first alignment keys AK1a may extend from the upper surface of the base layer SS in the vertical direction (Z direction) and protrude past (i.e., above or to the outside of) the first layer L1. For example, some of each of the plurality of first alignment keys AK1a may protrude upward from the first layer L1, and may be arranged inside (i.e., extend into or past a lower surface of) the second layer L2.

The plurality of second alignment keys AK2a may be respectively in contact with the plurality of first alignment keys AK1a. For example, each of the plurality of second alignment keys AK2a may surround some of the plurality of first alignment keys AK1a inside the second layer L2, and extend in the horizontal direction. For example, the plurality of second alignment keys AK2a may be in contact and coplanar with portions of side surfaces and upper surfaces of the plurality of first alignment keys AK1a, respectively.

An upper surface of each of the plurality of second alignment keys AK2a may have a planar shape, and a lower surface of each of the plurality of second alignment keys AK2a may include a bent portion corresponding to a portion of the plurality of first alignment keys AK1a in the second layer L2.

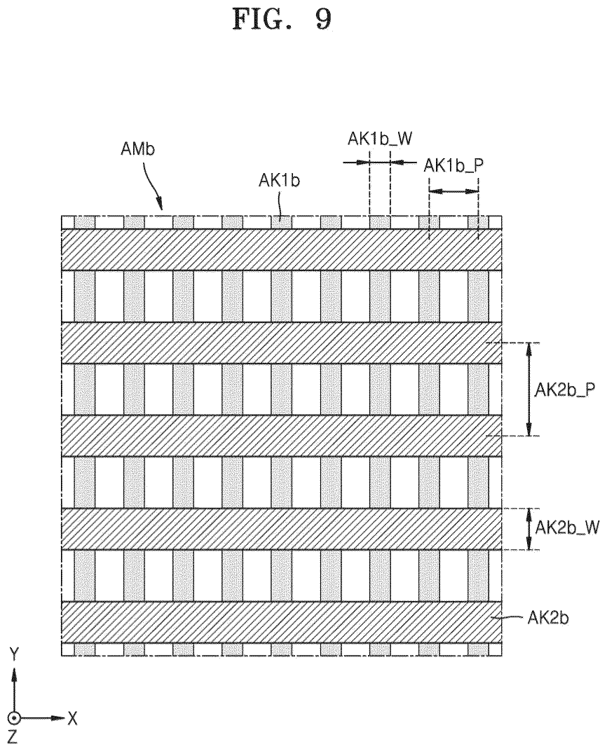

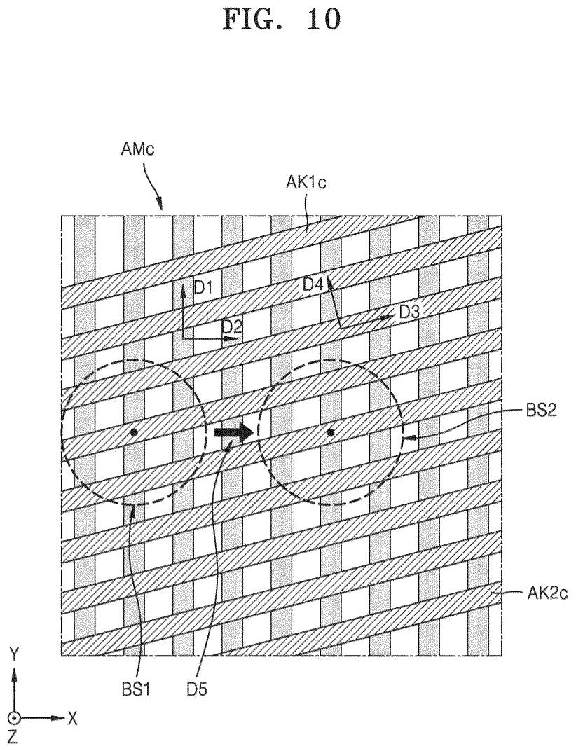

FIG. 9 is a schematic plan view of an alignment mark AMb according to an example embodiment. FIG. 10 is a schematic plan view of an alignment mark AMc according to an example embodiment. For example, FIGS. 9 and 10 are plan views of the plurality of alignment marks AMb and AMc on the semiconductor substrate W, respectively.

Most of the components constituting the alignment marks AMb and AMc and the materials constituting the components may be substantially the same as or similar to those described with reference to FIG. 4. Accordingly, for convenience of description, the difference between the alignment marks AMb and AMc of FIGS. 9 and 10, respectively, and the alignment mark AM of FIG. 4 described above is mainly described.

Referring to FIG. 9, the alignment mark AMb may include a plurality of first alignment keys AK1b and a plurality of second alignment keys AK2b. In a plan view, the plurality of first alignment keys AK1b and the plurality of second alignment keys AK2b may be arranged to form a grid pattern.

When a width of each of the plurality of first alignment keys AK1b is a first width AK1b_W, and a width of each of the plurality of second alignment keys AK2b is a second width AK2b_W, the first width AK1b_W may be different from the second width AK2b_W. For example, the first width AK1b_W may be less than the second width AK2b_W.

When a distance between a center of each of the plurality of first alignment keys AK1b and one adjacent first alignment key AK1b (i.e., a pitch of the plurality of first alignment keys AK1b) is a first distance AK1b_P, and a distance between a center of each of the plurality of second alignment keys AK2b and one adjacent second alignment key AK2b (i.e., a pitch of the plurality of second alignment keys AK2b) is a second distance AK2b_P, the first alignment key AK1b may be different from the second distance AK2b_P. For example, the first distance AK1b_P may be less than the second distance AK2b_P.

For example, because the first width AK1b_W is different from the second width AK2b_W, and the first distance AK1b_P is different from the second distance AK2b_P, the difference between the first measurement period (refer to F_AK1 in FIG. 7) of the first alignment key AK1b and the second measurement period (refer to F_AK2 in FIG. 7) of the second alignment key AK2b may be relatively increased. Accordingly, the first signal (refer to S_AK1 in FIG. 7) of the first alignment key AK1b may be separated from the second signal (refer to S_AK2 in FIG. 7) of the second alignment key AK2b, and thus the accuracy of overlay error correction may be increased.

Referring to FIG. 10, the alignment mark AMc may include a plurality of first alignment keys AK1c and a plurality of second alignment keys AK2c. The plurality of first alignment keys AK1c may extend in the first horizontal direction D1, and may be apart from each other in the second horizontal direction D2 perpendicular to the first horizontal direction D1. The plurality of second alignment keys AK2c may extend in the third horizontal direction D3, and may be apart from each other in the fourth horizontal direction D4 perpendicular to the third horizontal direction D3.

The third horizontal direction D3 may be inclined from the second horizontal direction D2 to the first horizontal direction D1. The third horizontal direction D3 may be different from the first horizontal direction D1 and the second horizontal direction D2. For example, the third horizontal direction D3 may be inclined by about 20° to about 35° or about 55° to about 70° with respect to the second horizontal direction D2.

The measuring apparatus (refer to 180 in FIG. 1) may move on the upper portion of each of the plurality of alignment marks AMc in the fifth horizontal direction D5, and measure the plurality of first alignment keys AK1c and the plurality of second alignment keys AK2c of each of the plurality of alignment marks AMc.

The fifth horizontal direction D5 may be the same as one of the first through fourth horizontal directions D1 through D4. For example, even when the fifth horizontal direction D5 is the same as one of the first through fourth horizontal directions D1 through D4, the number of first alignment marks AMc may not be the same as the number of second alignment marks AMc, which are measured while the measuring apparatus (refer to 180 in FIG. 1) moves.

Referring to FIG. 10, for example, when a measurement point measured by the measuring apparatus (refer to 180 in FIG. 1) moves from the first measurement point BS1 to the second measurement point BS2 in the fifth horizontal direction D5 that is the same as the second horizontal direction D2, the number of first alignment keys AK1 measured by the measuring apparatus 180 may be five, and the number of second alignment keys AK2 measured by the measuring apparatus 180 may be two.

However, example embodiments are not limited thereto, and the fifth horizontal direction D5 may be a direction in which the number of first alignment marks AMc measured while the measuring apparatus (refer to 180 in FIG. 1) moves is not the same as the number of second alignment marks AMc measured while the measuring apparatus (refer to 180 in FIG. 1) moves.

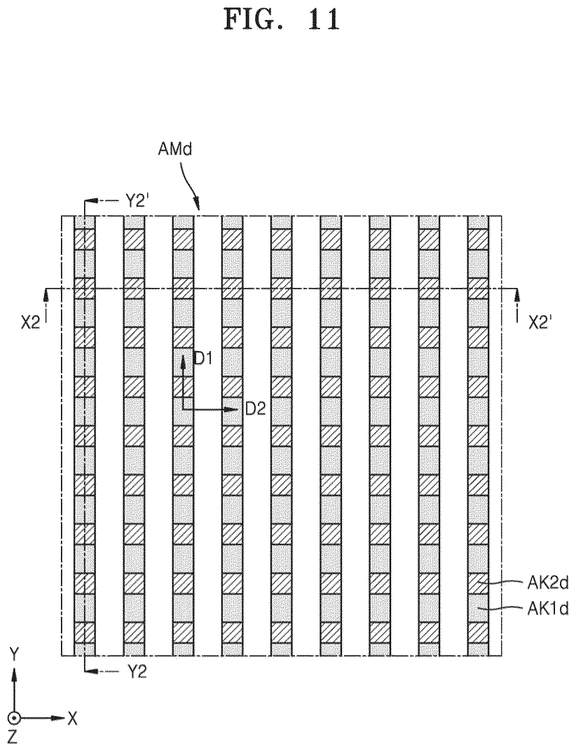

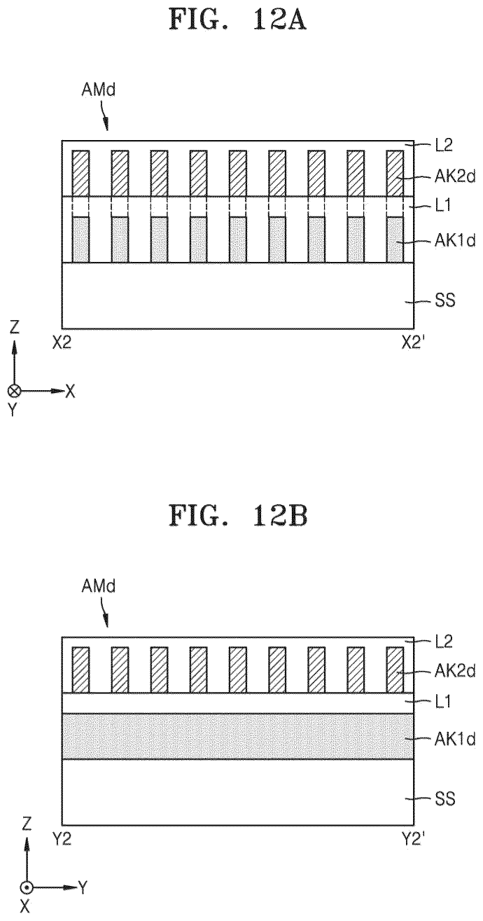

FIG. 11 is a schematic plan view of an alignment mark AMd according to an example embodiment. FIGS. 12A and 12B are schematic cross-sectional views of the alignment mark AMd of FIG. 11 taken along lines X2-X2′ and Y2-Y2′ in FIG. 11, respectively. For example, FIG. 11 is a plan view of one of a plurality of alignment marks AMd arranged on the semiconductor substrate W.

Most of the components constituting the alignment mark AMd and materials constituting the components may be substantially the same as or similar to those described with reference to FIGS. 4 and 5. Accordingly, for convenience of description, the difference between the alignment mark AMd of FIGS. 11, 12A, and 12B and the alignment mark AM of FIGS. 4, 5A, and 5B described above is mainly described.

Referring to FIGS. 11, 12A, and 12B, the alignment mark AMd may include a plurality of first alignment keys AK1d and a plurality of second alignment keys AK2d. The plurality of first alignment keys AK1d may be in the first layer L1, and the plurality of second alignment keys AK2d may be in the second layer L2. The plurality of first alignment keys AK1d may be below the plurality of second alignment keys AK2d in a vertical direction (Z direction).

The plurality of first alignment keys AK1d may extend in the first horizontal direction D1, and may be apart from each other in the second horizontal direction D2 perpendicular to the first horizontal direction D1. For example, in a plan view, each of the plurality of first alignment keys AK1d may have a rail shape extending in the first horizontal direction D1.

Each of the plurality of second alignment keys AK2d may have a protrusion shape extending in the vertical direction (Z direction). For example, a cross-section of each of the plurality of second alignment keys AK2d cut by a plane in parallel with the X-Y plane may have a polygonal shape such as a rectangular shape.

The plurality of second alignment keys AK2d may be arranged in a matrix form. The plurality of second alignment keys AK2d may be arranged in a matrix shape including a plurality of rows apart from each other in the first horizontal direction D1 and a plurality of columns apart from each other in the second horizontal direction D2.

In some example embodiments, all of the plurality of second alignment keys AK2d may overlap at least one of the plurality of first alignment keys AK1d in the vertical direction (Z direction). For example, the second alignment keys AK2d arranged on the same column among the plurality of second alignment keys AK2d may be above one first alignment key AK1d. For example, a separation distance between a center of each of a plurality of columns of the plurality of second alignment keys AK2d (i.e., a pitch of the plurality of second alignment keys AK2d) may be the same as a separation distance between a center of each of the plurality of first alignment keys AK1d (i.e., a pitch of the plurality of first alignment keys AK1d).

The measuring apparatus (refer to 180 in FIG. 1) may move on the upper portion of each of the plurality of alignment marks AMd in the fifth horizontal direction (refer to D5 in FIG. 4), and measure the plurality of first alignment keys AK1d and the plurality of second alignment keys AK2d of each of the plurality of alignment marks AMd. For example, the measuring apparatus 180 may simultaneously measure the plurality of first alignment keys AK1d and the plurality of second alignment keys AK2d of the alignment mark AMd, while passing on the upper portion of one alignment mark AMd one time.

In some example embodiments, the fifth horizontal direction (refer to D5 in FIG. 4) may be a direction inclined toward the first horizontal direction D1 with respect to the second horizontal direction D2. For example, the fifth horizontal direction D5 may be inclined by about 20° to about 35° or about 55° to about 70° in the first horizontal direction D1 with respect to the second horizontal direction D2.

For example, while the measuring apparatus 180 moves a certain distance in the fifth horizontal direction (refer to D5 in FIG. 4) on the alignment mark AMd, the number of first alignment keys AK1d may be different from the number of second alignment keys AK2d, which are passed by the measuring apparatus 180.

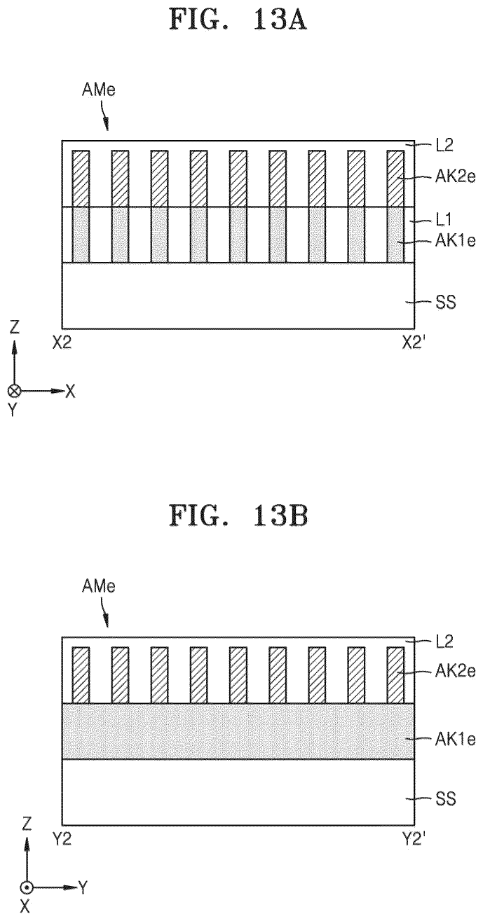

FIGS. 13A and 13B are schematic cross-sectional views of cut portions of an alignment mark AMe, according to example embodiments. FIG. 13A is a cross-sectional view in which the alignment mark AMe is cut by a plane in parallel with the X-Z plane, and FIG. 13B is a cross-sectional view in which the alignment mark AMe is cut by a plane in parallel with the Y-Z plane, respectively.

Most of the components constituting the alignment mark AMe and materials constituting the components may be substantially the same as or similar to those described with reference to FIGS. 4, 5A and B. Accordingly, for convenience of description, the difference between the alignment mark AMe of FIGS. 13A and 13B and the alignment mark AM of FIGS. 4, 5A, and 5B described above is mainly described.

Referring to FIGS. 13A and 13B, the alignment mark AMe may include a plurality of first alignment keys AK1e in the first layer L1 arranged on the base layer SS and a plurality of second alignment keys AK2e in the second layer L2 arranged on the first layer L1.

For example, in a plan view, a plurality of first alignment keys AK1e and a plurality of second alignment keys AK2e of the alignment mark AMe of FIGS. 13A and 13B may be arranged as illustrated in FIG. 11.

In contrast to in the alignment mark AMd in FIGS. 12A and 12B, in the alignment mark AMe in FIGS. 13A and 13B, the plurality of first alignment keys AK1e may respectively contact the plurality of second alignment keys AK2e. For example, an upper surface of each of the plurality of first alignment keys AK1e may be in contact and coplanar with a lower surface of each of the plurality of second alignment keys AK2e. For example, each of a plurality of first alignment keys AK1e may extend from a lower surface of the first layer L1 to an upper surface of the first layer L1. The plurality of second alignment keys AK2e may be respectively on the upper surface of the plurality of first alignment keys AK1e.

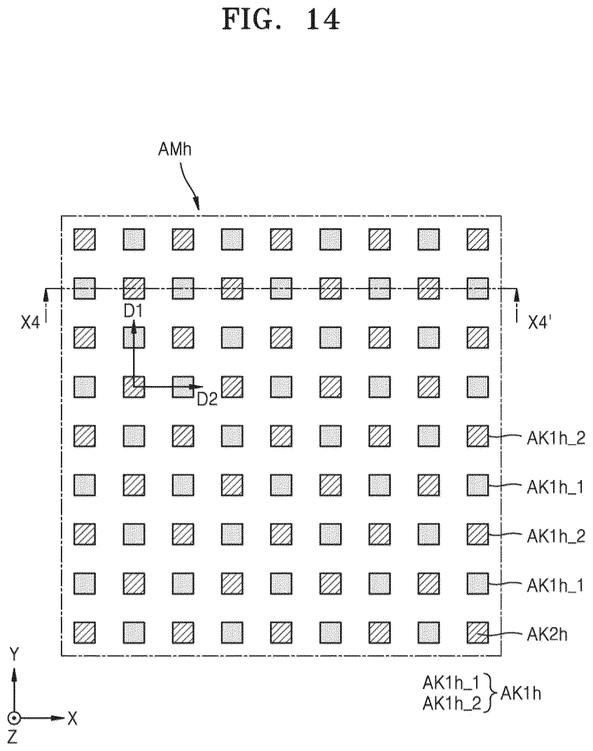

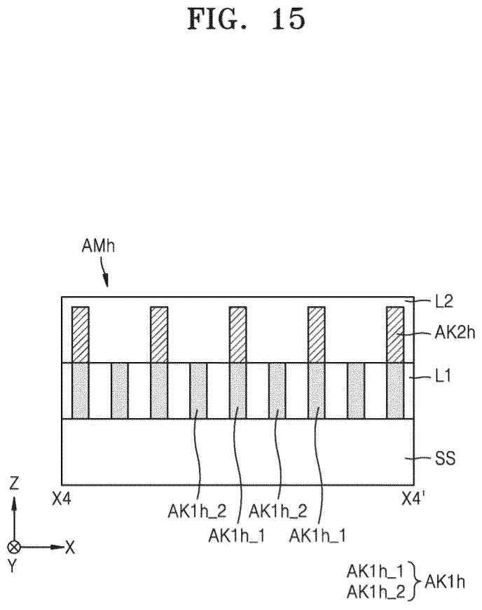

FIG. 14 is a schematic plan view of an alignment mark AMh according to an example embodiment. FIG. 15 is a schematic cross-sectional view of the alignment mark AKh in FIG. 14 taken along line X4-X4′ in FIG. 14.

For example, FIG. 14 is a plan view of one of a plurality of alignment marks AMh arranged on the semiconductor substrate W. Most of the components constituting the alignment mark AMh and the materials constituting the components may be substantially the same as or similar to those described with reference to FIG. 4. Accordingly, for convenience of description, the difference between the alignment mark AMh of FIGS. 14 and 15 and the alignment mark AM of FIG. 4 described above is mainly described.

Referring to FIGS. 14 and 15, the alignment mark AMh may include a plurality of first alignment keys AK1h in the first layer L1 thereof and a plurality of second alignment keys AK2h in the second layer L2 thereof.

Each of the plurality of first alignment keys AK1h and the plurality of second alignment keys AK2h may have a protrusion shape extending in the vertical direction (Z direction). For example, a cross-section of each of the plurality of first alignment keys AK1h cut by a plane in parallel with the X-Y plane may have a polygonal shape such as a rectangular shape. For example, a cross-section of each of the plurality of second alignment keys AK2h cut by a plane in parallel with the X-Y plane may have a polygonal shape such as a rectangular shape.

In some example embodiments, a width of each of the plurality of first alignment keys AK1h may be different from a width of each of the plurality of second alignment keys AK2h. An area of a cross-section of each of the plurality of first alignment keys AK1h may be different from an area of a cross-section of each of the plurality of second alignment keys AK2h. The plurality of first alignment keys AK1h may be arranged in a matrix shape. The plurality of first alignment keys AK1h may be arranged in a matrix shape including a plurality of rows apart from each other in the first horizontal direction D1 and a plurality of columns apart from each other in the second horizontal direction D2.

The plurality of second alignment keys AK2h may be arranged in a matrix shape. The plurality of second alignment keys AK2h may be arranged in a matrix shape including a plurality of rows apart from each other in the first horizontal direction D1 and a plurality of columns apart from each other in the second horizontal direction D2.

The plurality of first alignment keys AK1h may be divided into a first group and a second group. For example, a plurality of first alignment keys AK1h_1 included in the first group and a plurality of second alignment keys AK1h_2 included in the second group may be alternately arranged.

For example, adding a column number and a row number of each of the plurality of first alignment keys AK1h_1 included in the first group may be even, and adding a column number and a row number of each of the plurality of second alignment keys AK1h_2 included in the first group may be odd. For example, among the plurality of first alignment keys AK1h, the first alignment key AK1h at (1,1) may be included in the first group, and the first alignment key AK1h at (1,2) may be included in the second group.

Each of the plurality of second alignment keys AK2h may overlap each of the first plurality of alignment keys AK1h_1 included in the first group in the vertical direction (Z direction). For example, the second alignment key AK2h may not be above the plurality of first alignment keys AK1h_2 included in the second group. A separation space between the plurality of second alignment keys AK2h may be arranged above the plurality of first alignment keys AK1h_2 included in the second group.

For example, the number of plurality of second alignment keys AK2h may be less than the number of plurality of first alignment keys AK1h. For example, the number of plurality of second alignment keys AK2h may be equal to the number of plurality of first alignment keys AK1h_1 included in the first group. For example, the number of plurality of second alignment keys AK2 h may be about 50 % of the number of plurality of first alignment keys AK1h.

In some example embodiments, when the area of the cross-section of each of the plurality of first alignment keys AK1h is less than the area of the cross-section of each of the plurality of second alignment keys AK2h, corners of an upper surface of each of the plurality of first alignment keys AK1h_1 included in the first group may be under (and spaced apart from) a lower surface of each of the plurality of second alignment keys AK2h.

In some example embodiments, when the area of the cross-section of each of the plurality of first alignment keys AK1h is greater than the area of the cross-section of each of the plurality of second alignment keys AK2h, corners of a lower surface of each of the plurality of second alignment keys AK2h may be on an upper surface of each of the plurality of first alignment keys AK1h_1 included in the first group.

In some example embodiments, the plurality of first alignment keys AK1h_1 included in the first group may be in direct contact with the plurality of second alignment keys AK2h. For example, the upper surface of each of the plurality of first alignment keys AK1h_1 included in the first group may be in contact and coplanar with the lower surface of each of the plurality of second alignment keys AK2h. However, example embodiments are not limited thereto, and the plurality of first alignment keys AK1h_1 included in the first group and the plurality of second alignment keys AK2h may be apart from each other with an insulating layer of the first layer L1 therebetween in the vertical direction (Z direction).

The measuring apparatus (refer to 180 in FIG. 1) may move on the upper portion of each of the plurality of alignment marks AMh in the fifth horizontal direction (refer to D5 in FIG. 4), and measure the plurality of first alignment keys AK1h and the plurality of second alignment keys AK2h of each of the plurality of alignment marks AMh.

For example, the measuring apparatus 180 may simultaneously measure the plurality of first alignment keys AK1h and the plurality of second alignment keys AK2h of the alignment mark AMh, while passing on the upper portion of one alignment mark AMh one time.

In some example embodiments, the fifth horizontal direction (refer to D5 in FIG. 4) may be a direction inclined toward the first horizontal direction D1 with respect to the second horizontal direction D2. For example, the fifth horizontal direction D5 may be inclined by about 20° to about 35° or about 55° to about 70° in the first horizontal direction D1 with respect to the second horizontal direction D2.

In some example embodiments, the fifth horizontal direction (refer to D5 in FIG. 10) may be the same direction as the second horizontal direction D2. For example, the number of first alignment marks Ak1h and the number of second alignment marks Ak2h, which are measured while the measuring apparatus (refer to 180 in FIG. 1) moves in the fifth horizontal direction, may not be the same.

However, example embodiments are not limited thereto, and the fifth horizontal direction (refer to D5 in FIG. 10) may be a direction in which the number of first alignment marks Ak1h is not the same as the number of second alignment marks Ak2h, which are measured while the measuring apparatus (refer to 180 in FIG. 1) moves.

Based on the difference between the first measurement period (refer to F_AK1 in FIG. 7) of the first alignment key AK1h and the second measurement period (refer to F_AK2 in FIG. 7) of the plurality of second alignment keys AK2h, the first signal (refer to S_AK1 in FIG. 7) of the first alignment key AK1h may be distinguished from the second signal (refer to S_AK2 in FIG. 7) of the second alignment key AK2h.

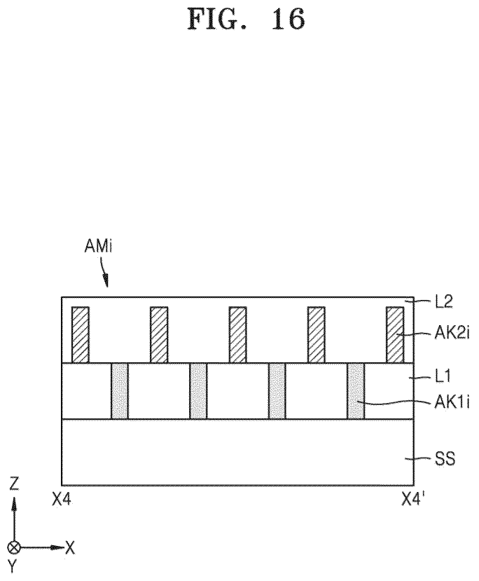

FIG. 16 is a schematic cross-sectional view of a cut portion of an alignment mark AMi, according to example embodiments. For example, FIG. 16 is a cross-sectional view of one of a plurality of alignment marks AMi arranged on the semiconductor substrate W, taken by using a planar surface in parallel with the X-Y plane.

Most of the components constituting the alignment mark AMi and the materials constituting the components may be substantially the same as or similar to those described with reference to FIG. 14. Accordingly, for convenience of description, the difference between the alignment mark AMi of FIG. 16 and the alignment mark AMh of FIGS. 14 and 15 described above is mainly described.

Referring to FIG. 16, the alignment mark AMi may include a plurality of first alignment keys AK1i in the first layer L1 arranged on the base layer SS and a plurality of second alignment keys AK2i in the second layer L2 arranged on the first layer L1. Each of the plurality of first alignment keys AK1i and the plurality of second alignment keys AK2i may have a protrusion shape extending in the vertical direction (Z direction).

Each of the plurality of first alignment keys AK1i and the plurality of second alignment keys AK2i may be arranged in a matrix shape including a plurality of rows apart from each other in the first horizontal direction (refer to D1 in FIG. 14) and a plurality of columns apart from each other in the second horizontal direction (refer to D2 in FIG. 14).

The plurality of first alignment keys AK1i may not overlap the plurality of second alignment keys AK2i in the vertical direction (Z direction). For example, each of the plurality of second alignment keys AK2i may be on separation spaces between each of the plurality of first alignment keys AK1i. For example, each of the plurality of second alignment keys AK2i may be horizontally spaced apart from each of the plurality of first alignment keys AK1i. In addition, each of the plurality of first alignment keys AK1i may be under separation spaces between each of the plurality of second alignment keys AK2i. In this regard, the plurality of first alignment keys AK1i may not overlap any of the plurality of second alignment keys AK2i along the vertical direction (Z direction).

For example, in a plan view, the shape in which the plurality of first alignment keys AK1i and the plurality of second alignment keys AK2i are arranged may be substantially the same as the shape illustrated in FIG. 14. However, in a cross-sectional view in which the alignment mark AMi is cut by a plane in parallel with the X-Z plane or a plane in parallel with the Y-Z plane, the plurality of first alignment keys AK1i and the plurality of second alignment keys AK2i may be arranged in a zig-zag shape.

While aspects of example embodiments have been particularly shown and described, it will be understood that various change in form and details may be made therein without departing from the spirit and scope of the following claims.

What is claimed is:

1. A substrate processing apparatus comprising:
a semiconductor substrate comprising a base layer, a first layer on the base layer, a second layer on the first layer, and a plurality of alignment marks in the first layer and the second layer; and
a measuring apparatus configured to analyze the plurality of alignment marks of the semiconductor substrate,
wherein the plurality of alignment marks comprises a plurality of first alignment keys in the first layer and a plurality of second alignment keys in the second layer,
wherein, in a plan view, the plurality of first alignment keys extend along a first horizontal direction, and are apart from each other along a second horizontal direction perpendicular to the first horizontal direction,
wherein, in the plan view, the plurality of second alignment keys extend along a third horizontal direction, and are apart from each other along a fourth horizontal direction perpendicular to the third horizontal direction, and
wherein the plurality of first alignment keys and the plurality of second alignment keys overlap along a vertical direction.

2. The substrate processing apparatus of claim 1, wherein the third horizontal direction is a same direction as the second horizontal direction.

3. The substrate processing apparatus of claim 2, wherein the measuring apparatus is configured to move on an upper portion of each of the plurality of alignment marks in a fifth horizontal direction, and to analyze the plurality of first alignment keys and the plurality of second alignment keys of each of the plurality of alignment marks, and
wherein the fifth horizontal direction is inclined toward the first horizontal direction with respect to the second horizontal direction.

4. The substrate processing apparatus of claim 3, wherein the fifth horizontal direction is inclined between 20° to 35°, or between 55° to 70° to the first horizontal direction, with respect to the second horizontal direction.

5. The substrate processing apparatus of claim 1, wherein the third horizontal direction is inclined toward the first horizontal direction with respect to the second horizontal direction, and
wherein the third horizontal direction is a different direction from the first horizontal direction and the second horizontal direction.

6. The substrate processing apparatus of claim 5, wherein the measuring apparatus is configured to move on an upper portion of each of the plurality of alignment marks in a fifth horizontal direction, and to analyze the plurality of first alignment keys and the plurality of second alignment keys of each of the plurality of alignment marks, and
wherein the fifth horizontal direction is same direction as one horizontal direction of the first through fourth horizontal directions.

7. The substrate processing apparatus of claim 1, wherein each of the plurality of first alignment keys has a first width,
wherein a pitch of the plurality of first alignment keys is a first distance,
wherein each of the plurality of second alignment keys has a second width,
wherein a pitch of the plurality of second alignment keys is a second distance,
wherein the first width is identical to the second width, and
wherein the first distance is identical to the second distance.

8. The substrate processing apparatus of claim 1, wherein each of the plurality of first alignment keys has a first width,
wherein a pitch of the plurality of first alignment keys is a first distance,
wherein each of the plurality of second alignment keys has a second width,
wherein a pitch of the plurality of second alignment keys is a second distance,
wherein the first width is different from the second width, and
wherein the first distance is different from the second distance.

9. The substrate processing apparatus of claim 1, wherein each of the plurality of first alignment keys extends along the second horizontal direction, and comprises a plurality of first sub-segments apart from each other along the first horizontal direction.

10. A substrate processing apparatus comprising:
a semiconductor substrate comprising a base layer, a first layer on the base layer, a second layer on the first layer, and a plurality of alignment marks in the first layer and the second layer; and
a measuring apparatus configured to analyze the plurality of alignment marks of the semiconductor substrate,
wherein the plurality of alignment marks comprises a plurality of first alignment keys in the first layer and a plurality of second alignment keys,
wherein each of the plurality of second alignment keys has a protrusion shape extending in a vertical direction, and
wherein, in a plan view, the plurality of second alignment keys are arranged in a matrix shape in which a plurality of columns apart from each other along a first horizontal direction and a plurality of rows apart from each other along a second horizontal direction perpendicular to the first horizontal direction are arranged.

11. The substrate processing apparatus of claim 10, wherein each of the plurality of first alignment keys has a protrusion shape extending in the vertical direction, and
wherein, in the plan view, the plurality of first alignment keys are arranged in a matrix shape in which a plurality of columns apart from each other along the first horizontal direction and a plurality of rows apart from each other along the second horizontal direction perpendicular to the second horizontal direction are arranged.

12. The substrate processing apparatus of claim 11, wherein a first group of the plurality of first alignment keys and a second group of the plurality of first alignment keys are alternately arranged, and
wherein each of the plurality of second alignment keys overlaps a corresponding first alignment key of the plurality of first alignment keys comprised in the first group along the vertical direction.

13. The substrate processing apparatus of claim 11, wherein each of the plurality of second alignment keys is in a separation space between each of the plurality of first alignment keys, and is offset from each of the plurality of first alignment keys along the vertical direction.

14. The substrate processing apparatus of claim 13, wherein the measuring apparatus is configured to move on an upper portion of each of the plurality of alignment marks in a fifth horizontal direction, and analyze the plurality of first alignment keys and the plurality of second alignment keys of each of the plurality of alignment marks, and
wherein the fifth horizontal direction is inclined toward the first horizontal direction with respect to the second horizontal direction.

15. The substrate processing apparatus of claim 10, wherein, in the plan view, the plurality of first alignment keys extend along the first horizontal direction, and are apart from each other along the second horizontal direction, and
wherein second alignment keys arranged on an identical column among the plurality of columns of the plurality of second alignment keys are arranged on corresponding first alignment keys among the plurality of first alignment keys.

16. The substrate processing apparatus of claim 15, wherein the measuring apparatus is configured to move on an upper portion of each of the plurality of alignment marks in a fifth horizontal direction, and analyze the plurality of first alignment keys and the plurality of second alignment keys of each of the plurality of alignment marks, and
wherein the fifth horizontal direction is inclined toward the first horizontal direction with respect to the second horizontal direction.

17. A substrate processing apparatus comprising:
an extreme ultra-violet (EUV) light source;
a mask stage;
a first optical device configured to allow EUV light from the EUV light source to be incident on an EUV mask on the mask stage;
a semiconductor substrate comprising a base layer, a first layer on the base layer, a second layer on the first layer, and a plurality of alignment marks in the first layer and the second layer;
a wafer stage configured to support the semiconductor substrate;
a second optical device configured to allow the EUV light reflected by the EUV mask to be incident on the semiconductor substrate; and
a measuring apparatus configured to analyze the plurality of alignment marks of the semiconductor substrate,
wherein each of the plurality of alignment marks comprises a plurality of first alignment keys in the first layer and a plurality of second alignment keys, and
wherein the plurality of first alignment keys and the plurality of second alignment keys overlap along a vertical direction.

18. The substrate processing apparatus of claim 17, wherein, in a plan view, the plurality of first alignment keys extend along a first horizontal direction, and are apart from each other along a second horizontal direction perpendicular to the first horizontal direction,
wherein, in the plan view, the plurality of second alignment keys extend along the second horizontal direction, and are apart from each other along the first horizontal direction,
wherein the measuring apparatus is configured to move on an upper portion of each of the plurality of alignment marks in a fifth horizontal direction, and analyze the plurality of first alignment keys and the plurality of second alignment keys of each of the plurality of alignment marks, and
wherein the fifth horizontal direction is inclined toward the first horizontal direction with respect to the second horizontal direction.

19. The substrate processing apparatus of claim 17, wherein each of the plurality of first alignment keys and each of the plurality of second alignment keys have a protrusion shape extending in the vertical direction,
wherein, in a plan view, each of the plurality of first alignment keys and each of the plurality of second alignment keys are arranged in a matrix shape in which a plurality of columns apart from each other along a first horizontal direction and a plurality of rows apart from each other along a second horizontal direction vertical to the first horizontal direction are included,
wherein a first group of the plurality of first alignment keys and a second group of the plurality of first alignment keys are alternately arranged,
wherein each of the plurality of second alignment keys overlaps the plurality of first alignment keys comprised in the first group along the vertical direction,
wherein the measuring apparatus is configured to move on an upper portion of each of the plurality of alignment marks in a fifth horizontal direction, and analyze the plurality of first alignment keys and the plurality of second alignment keys of each of the plurality of alignment marks, and
wherein the fifth horizontal direction is inclined toward the first horizontal direction with respect to the second horizontal direction.

20. The substrate processing apparatus of claim 17,
wherein, in a plan view, the plurality of first alignment keys extend along a first horizontal direction, and are apart from each other along a second horizontal direction perpendicular to the first horizontal direction,
wherein each of the plurality of second alignment keys has a protrusion shape extending in the vertical direction,
wherein, in the plan view, the plurality of second alignment keys are arranged in a matrix shape in which a plurality of columns apart from each other along the first horizontal direction and a plurality of rows apart from each other along the second horizontal direction,
wherein the measuring apparatus is configured to move on an upper portion of each of the plurality of alignment marks in a fifth horizontal direction, and analyze the plurality of first alignment keys and the plurality of second alignment keys of each of the plurality of alignment marks, and
wherein the fifth horizontal direction is inclined toward the first horizontal direction with respect to the second horizontal direction.
